(19) United States
(12) Patent Application Publication
(10) Pub. No.: US 2026/0101420 A1
(43) Pub. Date: Apr. 9, 2026

(54) INDUCTION COOKTOP

(71) Applicant: E.G.O. Elektro-Gerätebau GmbH, Oberderdingen (DE)

(72) Inventor: Thomas Föller, Schwaigern (DE)

(21) Appl. No.: 19/336,612

(22) Filed: Sep. 23, 2025

(30) Foreign Application Priority Data
Oct. 8, 2024 (DE) 102024128942.2

(51) Int. Cl. H05B 6/12; H05B 6/04; H05K 7/20

(52) U.S. Cl. CPC H05B 6/1209; H05B 6/04; H05K 7/20909

(57) ABSTRACT

An induction cooktop has a cooktop plate, induction heating coils thereunder, a power supply with power semiconductors for the induction heating coils and an electrical connection to the outside, wherein the power supply is arranged on a power printed circuit board and the electrical connection is arranged on a connection printed circuit board. At least one cooling device is also provided, which has at least one fan with a fan inlet as intake and with a fan outlet for blown-out air for cooling the power supply, a cooling air duct and at least one heat sink, to which the cooling air duct leads. The fan is arranged lower than the heat sink in a vertical direction which runs at right angles to the cooktop plate and to one of the printed circuit boards. The connection printed circuit board runs underneath the power printed circuit board, the connection printed circuit board has an electrical connection to the outside and the cooling air duct runs with a bend and deflection of 90° or of 180° between the fan outlet and the heat sink.

### CROSS-REFERENCE TO RELATED APPLICATIONS

This application claims priority to German Application No. 102024128942.2, filed Oct. 8, 2024, the contents of which are hereby incorporated herein in its entirety by reference.

### FIELD OF APPLICATION AND BACKGROUND OF THE INVENTION

The invention relates to an induction cooktop with a cooktop plate and induction heating coils thereunder and with a power supply and an electrical connection, for which a total of two printed circuit boards are provided. Furthermore, a cooling device is provided, which has a cooler and a cooling air duct leading to a heat sink, at which power semiconductors of the power supply are arranged for cooling purposes.

A cooling device is known from DE 10 2017 213 582 A1 which may inter alia also be used in a cooktop. In this case, a fan blows directly against a heat sink.

### Object and Solution

The object of the invention is to provide an induction cooktop as stated above with which prior art problems can be solved and which makes it possible in particular to keep the structure of the induction cooktop simple and compact and at the same time to achieve the best possible cooling.

This object is solved by an induction cooktop having a cooktop plate and induction heating coils thereunder, there being at least one induction heating coil and advantageously a plurality of induction heating coils, such as four to six for example. The induction cooktop also has a power supply for the induction heating coils which has power semiconductors, in particular for an inverter. Such a power supply is known in principle. The induction cooktop additionally has an electrical connection to the outside, which leads in particular to a household connection or to a building connection. The power supply is arranged on a power printed circuit board, while said electrical connection is arranged on a connection printed circuit board. The induction cooktop thus has at least these two printed circuit boards. Finally, the induction cooktop also has a cooling device, which has at least one fan with a fan inlet and a fan outlet. Air is sucked in at the fan inlet, as usual, and the sucked-in air is blown out at the fan outlet, the intention being to cool at least the power supply. To this end, a cooling air duct is provided for the blown-out air which is at least partly closed and adjoins the fan outlet, thus is preferably between fan and heat sink, or which adjoins the fan. The cooling air duct may have a simple or complicated course, and it may be short or long, as explained in greater detail below. Moreover, the cooling device additionally has a heat sink, to which the cooling air duct leads, so conveying the blown-out air to the heat sink for cooling, wherein the heat sink may be part of the cooling air duct. The stated power semiconductors rest against the heat sink, in order to be cooled. Still further components may also rest thereagainst or be cooled in another way at least indirectly, or optionally also directly, by the cooling air.

In accordance with the invention, it is provided that the induction cooktop has a vertical direction which runs at right angles to the cooktop plate and/or at right angles to one of the printed circuit boards, in particular to the power printed circuit board, wherein along this vertical direction the fan is arranged lower than the heat sink. This saves on installation space in the lateral direction. Furthermore, the connection printed circuit board runs or is arranged underneath the power printed circuit board. The two may advantageously be arranged parallel to one another with a spacing of between 0.5 cm and 10 cm. The connection printed circuit board has the electrical connection to the outside, advantageously in the form of plug connectors or screw terminals or other terminals arranged thereon. Finally, the cooling air duct runs with a bend or deflection of at least 80° or at least 90° between the fan outlet and the heat sink, such that the cooling air is deflected at least once by these at least 90°. Although this deflection of the cooling air does somewhat reduce the flow of cooling air and thus the cooling action, at the same time, such a bent cooling air duct is able to keep the installation space small or smaller than if it were to provide optimum flow by running in a perfectly straight line from the fan outlet to the heat sink.

The invention thus provides a relatively high level of integration with only a small installation space requirement, so reducing and/or keeping small the space requirement for the induction cooktop in particular underneath the cooktop plate and preferably in the lateral direction.

In one advantageous further development of the invention, the above-stated bend or deflection of the cooling air duct may be in an upwardly pointing direction, i.e., toward the cooktop plate. This causes the cooling air duct to run at a higher level downstream of this bend or deflection than the fan outlet, such that the cooling air duct causes the cooling air to be delivered or to flow to a point located above the fan or the fan outlet thereof. It is then at this location that the above-stated heat sink is arranged, with a type of two-tier structure thus being achieved, with the fan under the heat sink, which may reduce the sideways space requirement for the induction cooktop. The increased height which may result is less problematic.

Advantageously, by arranging the connection printed circuit board underneath the power printed circuit board, which is something which will be explained in greater detail below, said increased height may even be utilized as a type of integrated concept. In this way, an overall relatively compact and space-saving induction cooktop may be achieved, at least having a receiving housing or the like for the stated printed circuit boards.

In an alternative embodiment of the invention, said bend or deflection of the cooling air duct may extend in a lateral direction or have a lateral direction component. This may extend obliquely sideward and upward, particularly advantageously also only sideward. This bend or deflection then runs at least in part in a plane which is parallel to the cooktop plate or at right angles to the above-stated vertical direction. This ensures that the fan outlet lies at the same level as the cooling air duct and/or the heat sink. In this way, a structure can be achieved in which the fan at least does not necessarily increase the height of the induction cooktop or the receiving housing thereof for the printed circuit board. In this regard, in this embodiment of the invention the induction cooktop is of optimized or reduced height.

In the two above-stated embodiments, provision may preferably be made for the stated bend or deflection of the cooling air duct to cover not just 90°, i.e., as it were, only a partial change in direction. Advantageously, it may specifically be 180°, i.e., it may, as it were, cause a reversal of direction, but displaced upward or laterally. It is particularly preferably relatively precisely 180°, give or take 5°, such that a reversal in direction does actually take place, so enabling a particularly compact structure with regard to height or width. This 180° bend or deflection is present as a whole between fan outlet and heat sink. The heat sink may then advantageously be arranged and start directly downstream of the 180° bend or deflection. Although this 180° deflection may take place on the one hand in multiple stages, for example one of 90° and then another of 90°, because in this way a cooling air duct can be better integrated into the induction cooktop, advantageously the cooling air duct is present as an even bend or deflection, such that it may be evenly rounded, in particular taking the form of two mutually adjoining quarter circles or as a whole of one semicircle. In this way, the space requirement may itself be kept small, and efficient cooling air guidance may be achieved.

In a further embodiment of the invention, the fan outlet is radially oriented or extends tangentially from the fan. Additionally or alternatively, the fan inlet of the fan may be axially oriented, i.e., intake may take place axially. The fan outlet advantageously runs at right angles to the vertical direction, in particular like the cooling air duct in this region, where it starts. The fan inlet advantageously runs along a vertical direction, specifically downward. Particularly advantageously, the fan is arranged on a bottom and/or on a side wall of a receiving housing for the induction cooktop, such that it can suck in cooling air as well as possible from outside. Such embodiments of the fan and its intake and arrangement are known in principle from the prior art. Such a fan advantageously has a diameter or a width which is greater than its height or length, in particular the diameter is between 50% and 200% greater.

In one embodiment of the invention, the fan outlet is arranged in a plane which runs underneath the upper, power printed circuit board, such that it is arranged under the plane thereof. The fan or one of multiple fans of the induction cooktop may possibly be arranged actually underneath the power printed circuit board, so that the latter not only extends at a higher level but covers it. A plane of the lower, connection printed circuit board may run through the fan or the two components may be arranged at about the same height. This improves space utilization in the induction cooktop. Said fan may then advantageously lie laterally next to the connection printed circuit board, particularly advantageously in such a way that the latter does not need any cutout or the like for the fan.

The fan may preferably be arranged at least in part directly underneath the heat sink. An arrangement underneath a central region of the heat sink, when viewed in the longitudinal direction thereof, also results in good space utilization. Nevertheless, it may be advantageous for the fan not to blow cooling air directly at the heat sink, since this could otherwise result in unnecessary swirling and poor air flow through potentially the whole heat sink.

In an advantageous embodiment of the invention, the cooling air specifically runs from front to back through the heat sink or longitudinally therethrough. This may result in the best possible cooling as far as possible of the entire heat sink. Furthermore, in this way cooling air can actually be guided from front to back with regard to fitting of the induction cooktop into a work surface or the like. This enables the cooling air to exit at the back of the induction cooktop, such that a user standing in front of the induction cooktop is not affected thereby. The cooling air may here be blown out in a known manner in a region underneath the work surface or between the work surface and an item of kitchen furniture, oven or the like arranged thereunder.

A heat sink is advantageously of elongate configuration in a direction from front to back, again relative to the above-stated configuration and arrangement of the induction cooktop. Its length should be at least twice or three times as great as its width and its height, such that it may be regarded as a whole as long. The above-stated power semiconductors are then also advantageously arranged along this length, particularly advantageously next to one another, in order to ensure good and efficient cooling.

The heat sink preferably has cooling fins, which run next to or parallel to one another. Above cooling air may then flow through these cooling fins and cool them. The cooling fins are in turn arranged on a heat sink base or protrude therefrom. Advantageously, such a heat sink is produced or manufactured in a known manner by continuous casting. The power semiconductors may then rest against said heat sink base.

In one embodiment of the invention, the induction cooktop may have precisely one power printed circuit board. It may also have precisely one single connection printed circuit board. Separation of these two functions enables greater safety and a simpler structure. Under certain circumstances it is possible for both to be initially arranged or populated on a single blank and then separated, for example cut in two. Furthermore, the two printed circuit boards are electrically connected together by electrical connectors, in particular for power transfer. The two printed circuit boards are preferably arranged parallel to one another in the induction cooktop. Additionally or alternatively, they may exhibit the same area coverage or the same size. This enables structural size to be kept to a minimum.

A further development of the invention can provide for a cooling device to be arranged on each of opposing sides of the power printed circuit board, advantageously close to an outer edge. Each of these cooling devices may have its own heat sink, these being advantageously configured and arranged mirror-symmetrically to one another. Identical power semiconductors may accordingly be arranged on each of these two heat sinks, again mirror-symmetrically, in particular for an inverter and/or half-bridge or bridge circuits of the power supply. For the purpose of structural simplification, the two heat sinks may consist of the same basic profile, in particular they are identical.

In one possible further development of the invention, the cooling air duct may be formed in a lower region of the cooktop by a receiving housing for the two printed circuit boards or be configured thereon. The lower printed circuit board, advantageously the connection printed circuit board, may in this case be arranged fully in the receiving housing, in particular just above the bottom thereof. The upper power printed circuit board may be arranged in the upper region of the receiving housing, or alternatively in a part thereabove. Said receiving housing forms a 90° bend or deflection by way of a correspondingly configured duct wall, i.e., here it thus directly forms part of the cooling air duct. In this way, it is possible to save on additional components. In one possible further development of the invention, the receiving housing may completely accommodate said printed circuit boards and also the heat sinks or the entire cooling devices, optionally with an attachment placed on the top, which continues the receiving housing in an upward direction. The receiving housing is then, optionally with the attachment, fastened to the underside of the cooktop plate, advantageously in a conventional manner using adhesively bonded mounts. The remaining bend or deflection of the cooling air duct, advantageously by a further 90°, may be formed at the top by an attachment or superstructure. This is fastened to the receiving housing and may form a cooling air duct along one side and preferably on both sides.

In an advantageous further development of the invention, a lower region of the cooling air duct, which adjoins the stated fan outlet, may be formed by the receiving housing. At the top, the cooling air duct may be formed by the bottom of a housing part or attachment extending thereover, or alternatively by the underside of the heat sink itself. In this case too, said heat sink may run as far as up to or shortly before said bend or deflection, so that the cooling air can enter it at as early a point as possible. The heat sink may be of elongate configuration and run up to a rear end of the housing. The heat sink itself may then form part of the cooling air duct, or alternatively a housing may have separate walls which define the cooling air duct, the heat sink then extending within this defined space.

The power printed circuit board may advantageously have an inverter, a microcontroller and further components. It also has electrical connections for the induction heating coils. Preferably, electrical connections are also provided for an operating device, which is then in turn separately arranged, in particular is arranged on a supporting plate on which the induction heating coils are also arranged. Alternatively, a housing could be provided which has a holder for the operating device directly integrated into it.

The connection printed circuit board advantageously has a power pack, the electrical connection to the outside for a household connection and optionally also fuses, for example conventional melting fuses. The electrical connection is arranged in such a way that it can be reached from the outside even if the induction cooktop or receiving housing is not open. The electrical connection may be concealed by a separate lid or the like once connection has taken place.

These and further features are revealed in the description and in the drawings as well as in the claims, wherein the individual features can each be realized singly or severally in the form of sub-combinations in one embodiment of the invention and in other fields, and can represent advantageous and per se protectable embodiments, for which protection is claimed here. The subdivision of the application into individual sections and sub-headings does not limit the statements made thereunder in their general validity.

### BRIEF DESCRIPTION OF THE DRAWINGS

An exemplary embodiment of the invention is illustrated schematically in the drawings and explained in greater detail below. In the drawings:

FIG. 1 is a simplified lateral sectional representation through an induction cooktop fitted in a work surface,

FIG. 2 is an oblique view onto the induction cooktop as shown in FIG. 1 without supporting plate, induction heating coils and cooktop plate, with a power printed circuit board visible,

FIG. 3 shows an upper attachment, which contains the power printed circuit board and is placed onto a lower receiving housing,

FIG. 4 is an oblique view onto the lower receiving housing, which is open at the top and contains the connection printed circuit board,

FIG. 5 is an oblique view which is somewhat shallower compared to FIG. 2, is partially sectional at the side, and looks onto the cooling air duct, which transitions into the heat sink in the upper cooling air duct,

FIG. 6 is a schematic side view onto the configuration as shown in FIG. 5 showing the course taken by the 180°-deflected cooling air, indicated by arrows,

FIG. 7 is an enlarged sectional representation through the lower receiving housing with attachment placed on the top, cooling air duct and heat sink,

FIG. 8 is an oblique view from below onto the receiving housing with bottom, electrical connection and intake grilles for the two fans,

FIG. 9 is an oblique bottom view of an alternative embodiment of a receiving housing with only 90° deflection of the cooling air,

FIG. 10 is a partially sectional view of the receiving housing of FIG. 9.

### DETAILED DESCRIPTION OF THE EXEMPLARY EMBODIMENT

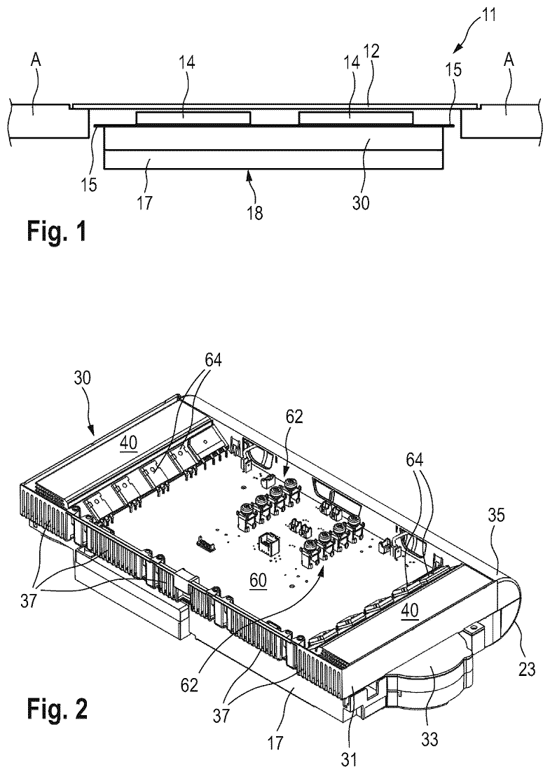

FIG. 1 is a sectional representation showing how an induction cooktop according to the invention is fitted into a cutout in a work surface A. The induction cooktop 11 here has a cooktop plate 12, which is let in flush into the work surface A. Induction heating coils 14 are pressed from below against an underside of the cooktop plate 12. These induction heating coils 14 rest on a supporting plate 15. A lower receiving housing 17 which has an attachment 30 placed on the top is provided under the supporting plate 15 in such a way that the upper attachment 30 rests against or lies on the underside of the supporting plate 15. This structure is known from the prior art, at least if the lower receiving housing 17 and the attachment 30 are considered to be an overall housing. The receiving housing 17 and the attachment 30 are additionally fastened to the underside of the cooktop plate 12, for example screwed to mounts adhesively bonded thereon or the like.

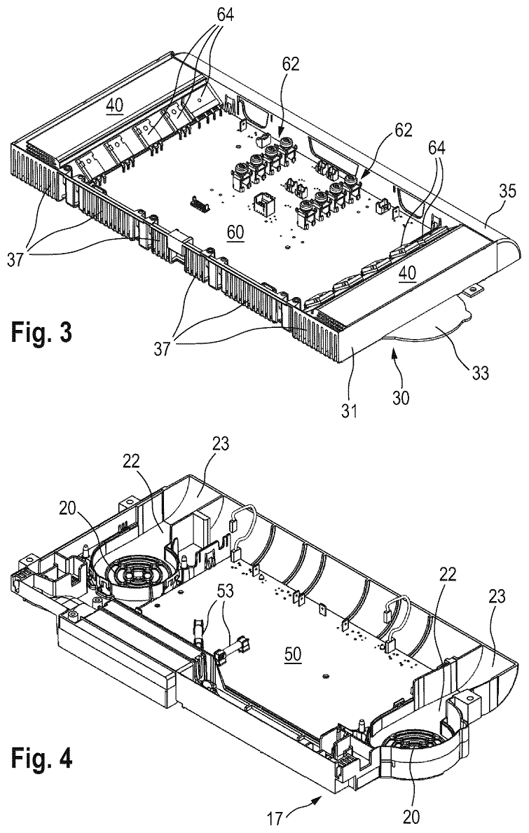

In the oblique representation of FIG. 2, supporting plate 15, induction heating coils 14 and cooktop plate 12 have been removed from the induction cooktop 11 of FIG. 1. The figure shows the overall holder for the induction cooktop 11, consisting of the lower receiving housing 17, which is shown in the same viewing direction in FIG. 4 as in FIG. 2, and the upper attachment 30 placed thereon, which is shown in the same way in FIG. 3. In the lower receiving housing 17, which has a bottom which is largely closed apart from two laterally molded-in intake grilles 20, a lower cooling air duct 22 is provided on each of the outer sides starting from these intake grilles 20, as it were in each case adjoining the intake grille 20, wherein fans 21 in the form of per se known fans are arranged over the round intake grilles 20. These fans suck air in axially and blow this sucked-in air out radially. The lower cooling air duct 22 is defined by lateral walls and by the bottom 18 of the lower receiving housing 17 and transitions into a lower quarter round 23, these starting an upward deflection of the blown-out air. This quarter round may be generally rounded and is advantageously configured, as is apparent from FIG. 6, precisely as a rounded quarter circle. At the top, the lower cooling air duct 22 is closed by a bottom 32 of the upper attachment 30.

An above-described connection printed circuit board is arranged, advantageously conventionally mounted, in the lower receiving housing 17. The connection printed circuit board 50 here by way of example has two melting fuses 53 on its upper side. Further components, such as for example a power pack or a switched-mode power supply, may be provided on the top of the connection printed circuit board 50. The oblique bottom view of FIG. 8 reveals how an above-mentioned electrical connection 52 with a plurality of screw terminals is provided which is advantageously also provided on the underside of the connection printed circuit board 50. The electrical connection 52 is provided in a cutout in the bottom 32, and can be used to connect the induction cooktop 11 electrically to a household connection.

FIG. 3 shows the upper attachment 30, which has roughly the same base area as the lower receiving housing 17 and is fastened thereto, thereby forming the overall holder for the induction cooktop 11. The upper attachment 30 has an upper cooling air duct 31, which runs above the lower cooling air duct 22. From this there departs, as it were mirror-symmetrically to the lower quarter round 23, an upper quarter round 35. The two quarter rounds 23 and 35 achieve 180° reversal of the cooling air flow, see in this respect also FIG. 6. The bottom 32 of the attachment 30 separates the lower cooling air duct 22 and the upper cooling air duct 31.

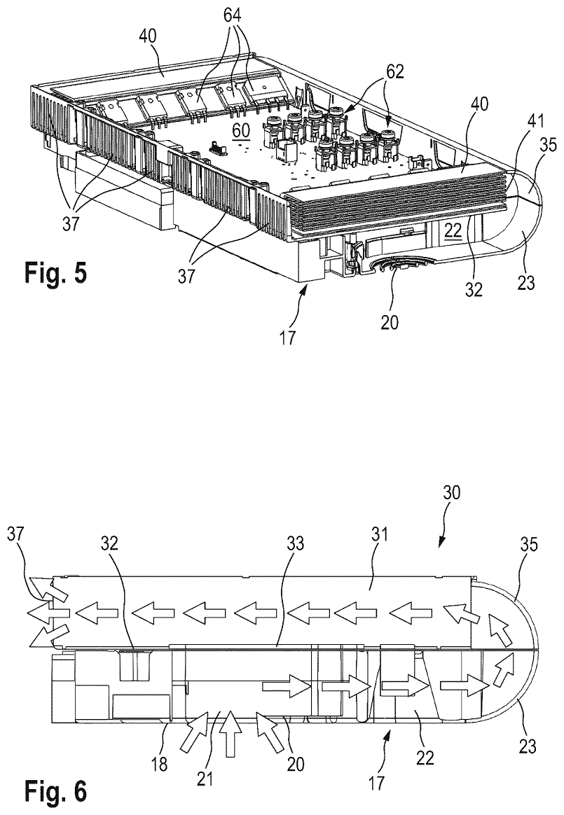

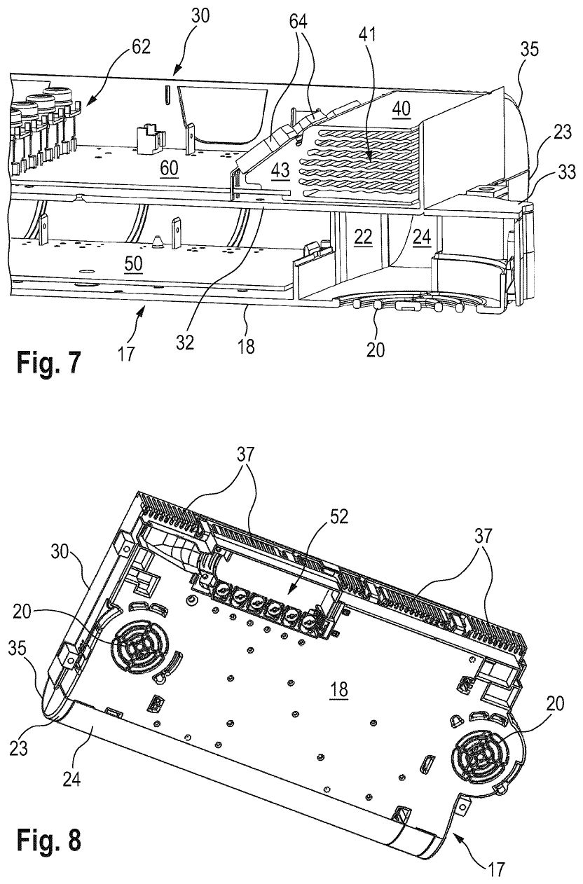

According to the sectional representations of FIGS. 5 and 7, in the upper cooling air duct 31 the upper quarter round 35 is directly adjoined by a heat sink 40, which thus largely occupies or fills the upper cooling air duct 31. The heat sink 40, as shown in particular by the sectional representation of FIG. 7, takes the form of an elongate special profile, with a beveled heat sink base 43 toward the middle of the upper attachment 30, from which protrude cooling fins 41 running largely parallel to one another and which are of undulating configuration. The cooling air flows through the interspaces thereof, as shown in FIG. 6. The upper cooling air duct 31 guides the air exiting from the heat sink 40 or the cooling fins 41 thereof to vent grilles 37 on the rear wall of the upper attachment 30. This is because when fitted, the quarter rounds 23 and 35 are at the front or form a front side of the induction cooktop 11, thus pointing to a front or the like of an item of furniture on which the work surface A has been placed. The vent grilles 37 point backward, i.e., backward into the stated item of furniture or toward a wall.

The upper attachment 30 has a laterally protruding fan cover 33, advantageously running in the same plane as a bottom 32 and which continues on in the same direction. This protruding fan cover 33 covers the fan 21 at the top, in accordance with FIG. 6. As a comparison of FIGS. 2 and 4 shows, it is provided only on the left-hand fan 21 (viewed from the front). The other fan 21 is completely covered by the bottom 32 of the upper attachment 30.

Furthermore, the upper attachment 30 has a power printed circuit board 60, on which, by way of example, coil connections 62 are provided which may also take the form of screw terminals. These serve as electrical connection of the induction heating coils 14.

Furthermore, power semiconductors 64 are provided on the top of the power printed circuit board 60. For cooling purposes, these are placed against the oblique regions of the heat sink bases 43 of the two heat sinks 40 to ensure the necessary cooling. Further above-mentioned components may likewise be provided on the power printed circuit board 60. An operating device for the induction cooktop 11 is advantageous electrically connected by cable, like the induction heating coils 14, and may be placed onto the supporting plate 15. Alternatively, an operating device may also protrude upward in a housing through a corresponding opening in the supporting plate 15.

From the representation in FIG. 6, it is apparent that the fans 21 are arranged lower than the heat sinks 40 when viewed in the vertical direction, which runs at right angles to the surface of the cooktop plate 12. In particular, the fans 21 are arranged at least in part underneath and thus also lower than the heat sink 40. As a result of this and of the 180°-deflected course of the cooling air in the cooling air duct with lower cooling air duct 22 and upper cooling air duct 31, a compact structure may be achieved for the induction cooktop 11 as a whole. Good through-flow of cooling air through the heat sinks 40 is achieved. The long configuration of the two heat sinks 40 also allows all necessary power semiconductors 64 to rest thereagainst without these being too close together. Providing the two printed circuit boards, the connection printed circuit board 50 and the power printed circuit board 60, arranged one above the other means that the combination of lower receiving housing 17 and upper attachment 30 is in any event structurally quite tall, such that the fans 21 can be arranged to the side thereof. In an alternative embodiment, other fans may also be used.

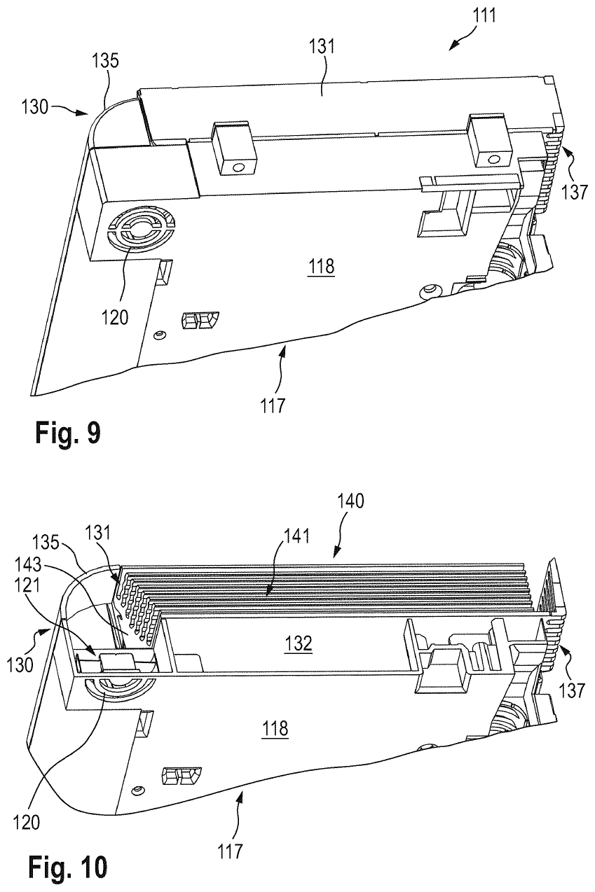

Like FIG. 8, but turned around somewhat, FIG. 9 shows an oblique bottom view of an alternative embodiment of an induction cooktop 111 with corresponding modified receiving housing 117. The receiving housing 117 has a bottom 118 and an intake grille 120 close to a front side or front edge in a front portion of the receiving housing 117. It is apparent from the partial section of FIG. 10 that a fan 121 is arranged above this intake grille 120, this fan taking the form of an exclusively axial-flow fan, unlike the fan 21 described above. It thus sucks the air in vertically from the bottom upward and blows it out again at the top into an upper cooling air duct 131. The cooling air blown out vertically upward is deflected 90° to the right, i.e., approximately at a right angle, by an upper quarter round 135 of the cooling air duct 131 or of the upper attachment 130. At that point is located the inlet into a heat sink 140, which has a heat sink base 143 and cooling fins 141 protruding therefrom. This heat sink 140 is of similar configuration to the heat sink 40 according to FIG. 5. However, at the start of the upper cooling air duct 131 and above the fan 121 the cooling fins 141 are obliquely cut off in such a way that cooling air blown upward and deflected to the right by the upper quarter round 135 can flow as well as possible into the interspaces between the cooling fins 141. In this case, the cooling air duct 131 is substantially formed in the heat sink 140 and by a bottom 132 of the upper attachment 130.

This exemplary embodiment of FIGS. 9 and 10 thus shows that deflection of the cooling air or of the cooling air duct by around 90° can be achieved and the configuration needed therefor. This makes it possible to use an exclusively axial-flow fan, which may possibly generate a stronger air flow and be of simpler construction. This may possibly compensate for the power losses arising from 90° deflection. Further air baffles or other air guides could additionally be provided in the relatively short region of the cooling air duct 131 between an outlet of the fan 121 and entry of the cooling air into the heat sink 140. Corresponding embodiments are sufficiently known in the art. The course of the cooling air within the substantial length of the cooling air duct 131 or in the heat sink 140 and its exit back out of the vent grille 137 may be as previously described. Likewise, the entire inner workings of the receiving housing 117 with the connection printed circuit board 50 and of the upper attachment 130 with a power printed circuit board may be configured as explained above.

1. An induction cooktop with:
a cooktop plate,
induction heating coils under said cooktop plate,
a power supply with power semiconductors for said induction heating coils,
an electrical connection to an outside,
said power supply being arranged on a power printed circuit board and said electrical connection being arranged on a connection printed circuit board, and
at least one cooling device, said cooling device having:
at least one fan with a fan inlet as intake and with a fan outlet for blown-out air for cooling at least said power supply,
a cooling air duct for blown-out cooling air, said cooling air duct being at least partly closed and adjoining said fan outlet,
at least one heat sink, wherein said cooling air duct leads to said at least one heat sink, wherein said power semiconductors rest against said heat sink for cooling purposes,
wherein
said fan is arranged lower than said heat sink in a vertical direction, wherein said vertical direction runs at right angles to said cooktop plate or at right angles to one of said printed circuit boards,
said connection printed circuit board runs underneath said power printed circuit board,
said connection printed circuit board has an electrical connection to an outside, and
said cooling air duct runs with a bend or with a deflection of at least 90° between said fan outlet and said heat sink.

2. The induction cooktop as claimed in claim 1, wherein said bend or said deflection of said cooling air duct is in an upward direction, such that said cooling air duct runs at a higher level downstream of said bend or of said deflection than said air outlet.

3. The induction cooktop as claimed in claim 1, wherein said bend or said deflection of said cooling air duct is at least in part in a plane at right angles to said vertical direction or wherein said cooling air duct runs at least in part in a plane at right angles to said vertical direction.

4. The induction cooktop as claimed in claim 3, wherein said fan outlet lies at a level being the same level as said cooling air duct or as said heat sink.

5. The induction cooktop as claimed in claim 1, wherein said bend or said deflection of said cooling air duct between said fan outlet and said heat sink covers 180°, said 180° bend or said 180° deflection being evenly rounded.

6. The induction cooktop as claimed in claim 5, wherein said heat sink is arranged directly downstream of said 180° bend or said 180° deflection and starts at said point.

7. The induction cooktop as claimed in claim 1, wherein said fan outlet of said fan is radially oriented, said fan outlet being oriented at right angles to said vertical direction.

8. The induction cooktop as claimed in claim 1, wherein said fan inlet of said fan is axially oriented, said fan inlet being oriented downward along said vertical direction.

9. The induction cooktop as claimed in claim 1, wherein said fan outlet is arranged in a plane underneath said power printed circuit board.

10. The induction cooktop as claimed in claim 1, wherein a plane of said connection printed circuit board runs through said fan, wherein said fan is arranged laterally next to said connection printed circuit board.

11. The induction cooktop as claimed in claim 1, wherein said fan is arranged at least in part directly underneath said heat sink.

12. The induction cooktop as claimed in claim 1, wherein said cooling air runs through said heat sink from a front of said induction cooktop to a back of said induction cooktop, said heat sink being of elongate configuration in a direction from said front to said back.

13. The induction cooktop as claimed in claim 1, wherein a length of said heat sink is at least twice or at least three times as great as its width and its height.

14. The induction cooktop as claimed in claim 1, wherein said heat sink has cooling fins, said cooling fins running next to one another or parallel to one another and are spaced relative to one another, said cooling air flowing through said cooling fins, said cooling fins being arranged on a heat sink base and protruding from said heat sink base, and said power semiconductors rest for cooling purposes against said heat sink base.

15. The induction cooktop as claimed in claim 1, having exactly one said power printed circuit board and precisely one said connection printed circuit board, said power printed circuit board and said connection printed circuit board being arranged parallel to one another or being configured having same area size.

16. The induction cooktop according to claim 1, wherein a cooling device is arranged on each of opposing sides of said power printed circuit board.

17. The induction cooktop as claimed in claim 16, wherein said heat sinks of said cooling devices are configured and arranged mirror-symmetrically.

18. The induction cooktop as claimed in claim 1, wherein said cooling air duct is formed in a lower region by a receiving housing for said printed circuit boards and is configured on said printed circuit boards, said receiving housing forming a 90° bend or a 90° deflection by way of a correspondingly configured duct wall, said receiving housing completely accommodating said printed circuit boards and said heat sinks and being fastened to an underside of said cooktop plate, and said remaining bend or said remaining deflection being formed by an attachment, said attachment being fastened to said receiving housing and running along exactly one side.

19. The induction cooktop as claimed in claim 18, wherein a lower region of said cooling air duct adjoining said fan outlet is formed by said receiving housing, said cooling air duct here being covered at a top by an underside of said heat sink, said heat sink running as far as a start of said bend or of said deflection and said cooling air duct being guided at said end as far as a rear end face of said heat sink.

20. The induction cooktop as claimed in claim 19, wherein said cooling air exits from said heat sink at an opposite end and exits to a rear from said induction cooktop or from said receiving housing.

21. The induction cooktop as claimed in claim 1, wherein said power printed circuit board has an inverter, a microcontroller and display elements and operating elements of an operating device for said induction cooktop and electrical connections for said induction heating coils.

22. The induction cooktop as claimed in claim 1, wherein said connection printed circuit board has a power pack, said electrical connection to an outside for a household connection and fuses.
